(19) United States
(12) Patent Application Publication
(10) Pub. No.: US 2014/0312189 A1
(43) Pub. Date: Oct. 23, 2014

(54) MOUNTING APPARATUS FOR INPUT/OUTPUT DEVICE

(71) Applicants: HON HAI PRECISION INDUSTRY CO., LTD., New Taipei (TW); HONG FU JIN PRECISION INDUSTRY (WuHan) CO., LTD., Wuhan (CN)

(72) Inventors: DAN YU, Wuhan (CN); ZHI-MING ZHU, Wuhan (CN); MING-HUI LUO, Wuhan (CN); SAN-YONG YANG, Wuhan (CN)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 14/084,858

(22) Filed: Nov. 20, 2013

(30) Foreign Application Priority Data
Apr. 23, 2013 (CN) 2013101416715

(51) Int. Cl. H05K 5/02

(52) U.S. Cl. CPC H05K 5/0217
USPC 248/224.7

(57) ABSTRACT

A mounting apparatus includes a securing plate and a mounting tray. The securing plate defines an opening and includes a bottom surface and a top surface opposite to the bottom surface. The mounting tray is used to secure input/output devices and includes a positioning portion and a resilient portion. The positioning portion is attached to the bottom surface. The resilient portion includes a resilient block clipped with a first edge of the opening. The resilient portion is deformable to disengage the resilient block from the first edge of the opening.

### BACKGROUND

1. Technical Field

The present disclosure relates to mounting apparatuses, and particularly to a mounting apparatus for securing input/output devices in an electronic device.

2. Description of Related Art

Computer systems usually include multiple input/output devices, and the input/output devices are secured in a mounting tray. The mounting tray is often secured to a rear plate of a chassis by screws, which can be very inconvenient and laborious. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, cutaway view of a mounting apparatus and a plurality input/output devices in accordance with an embodiment.

FIG. 2 is similar to FIG. 1, but viewed from a different aspect.

FIG. 3 is similar to FIG. 1, but viewed from a different aspect.

FIG. 4 is an assembled view of the mounting apparatus and the plurality of input/output devices of FIG. 1.

FIG. 5 is similar to FIG. 4, but viewed from a different aspect.

FIG. 6 is an assembled view of the mounting apparatus and the plurality of input/output devices of FIG. 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

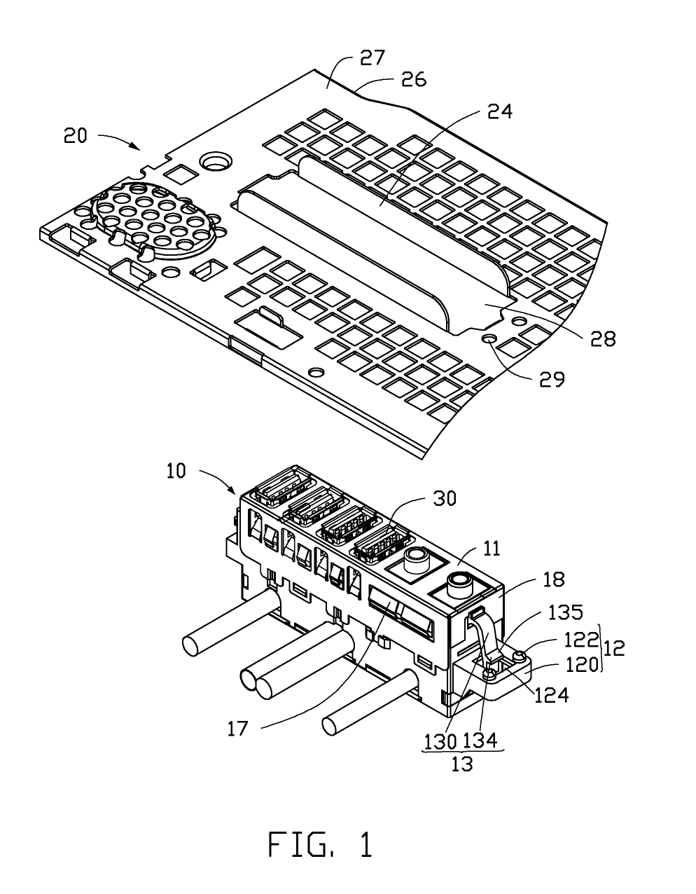

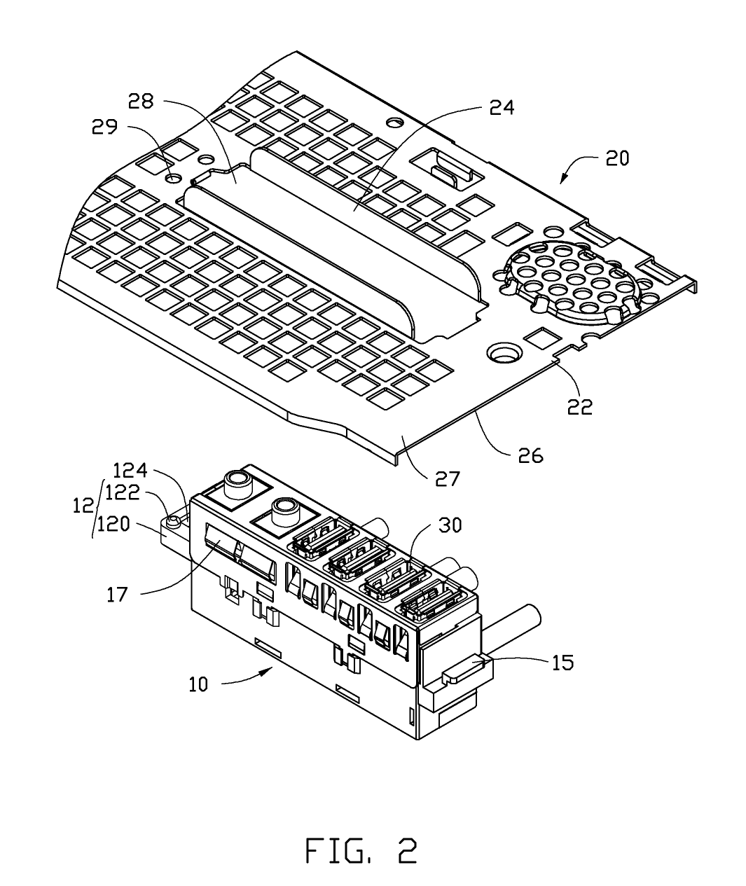

FIGS. 1-3 illustrate a mounting apparatus in accordance with an embodiment for securing a plurality of input/output devices 30. The mounting apparatus comprises a mounting tray 10 and a securing plate 20 of a computer case (not shown). The mounting tray 10 is used to secure the plurality of input/output devices 30.

The mounting tray 10 comprises a first sidewall 18 and a second sidewall 19 opposite to the first sidewall 18. A positioning portion 12 and a resilient portion 13 extend from the first sidewall 18. The positioning portion 12 comprises a main body 120 and two positioning posts 122 located on the main body 120. The main body 120 defines a through hole 124. The resilient portion 13 is located above the positioning portion 12 and comprises a resilient arm 130 and a clipping block 134 located on the resilient arm 130. The resilient arm 130 extends through the through hole 124 and moveable in the through hole 124. The clipping block 134 comprises a guiding surface 135. In one embodiment, the guiding surface 135 is slanted. A clamping piece 15 extends from the second sidewall 19. In one embodiment, the clamping piece 15 is L-shaped. Two resisting portions 17 are located opposite long sidewall of the mounting tray 10.

The securing plate 20 comprises a bottom surface 26 and a top surface 27 opposite to the bottom surface 26. An opening 28 and two positioning holes 29 are defined in the securing plate 20. Two resisting panels 24 extend from opposite edges of the opening 28 and located on the top surface 27. In one embodiment, the two resisting panels 24 are substantially parallel to each other, and the two positioning holes 29 are located on one end of the opening 28.

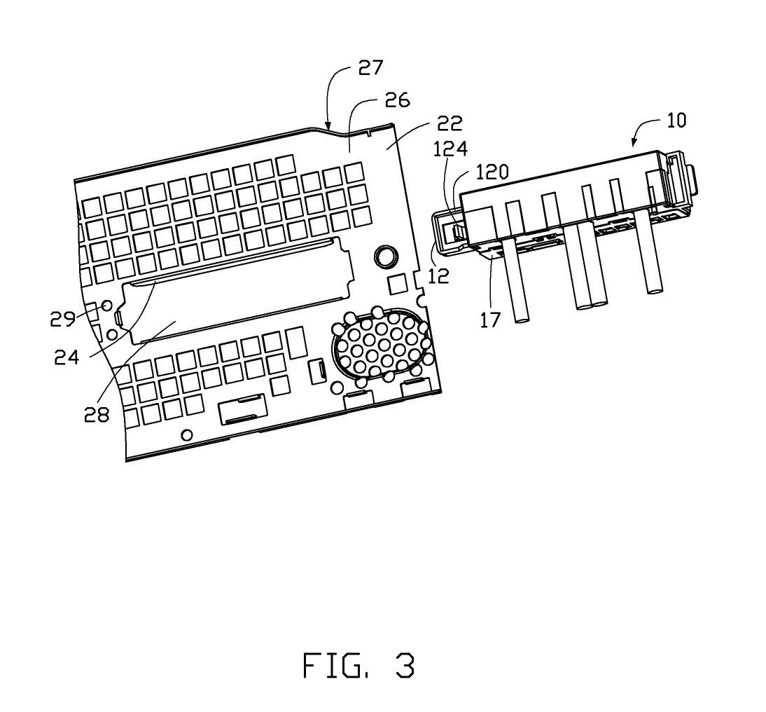

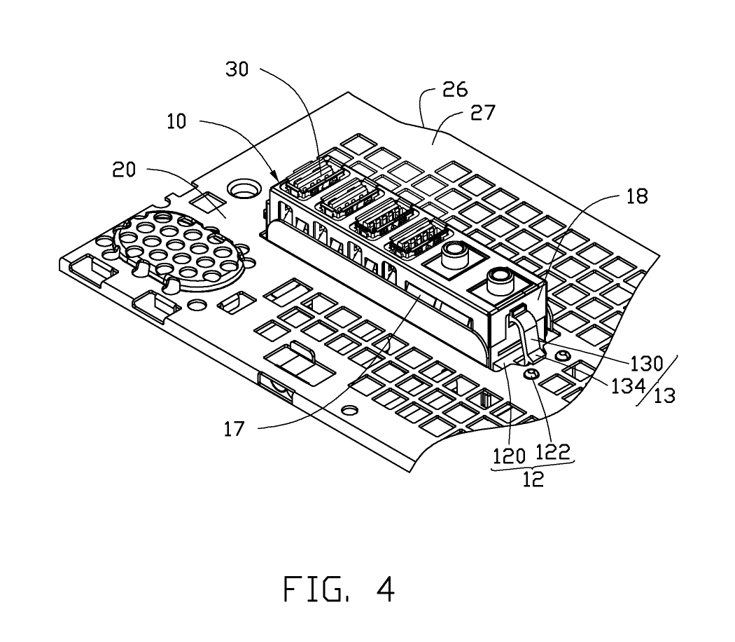

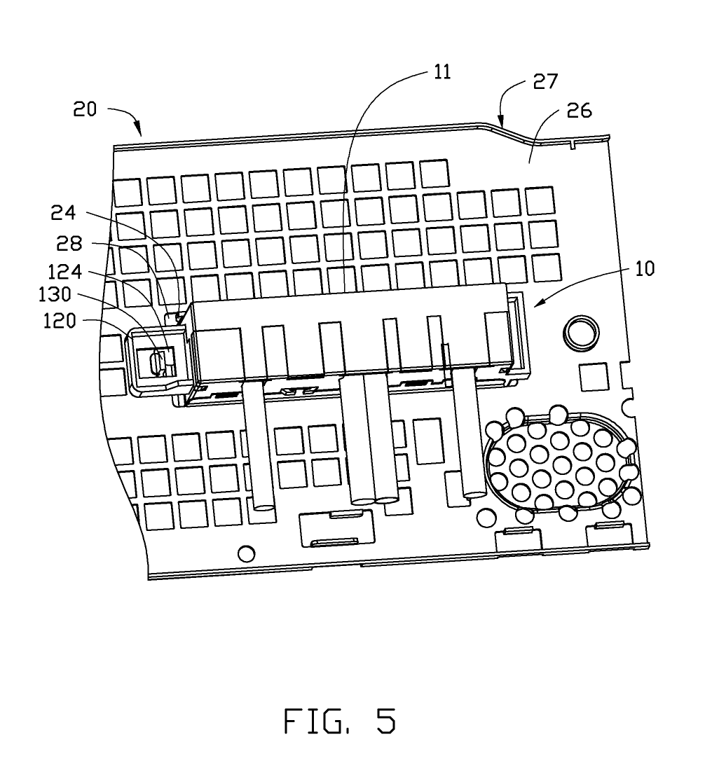

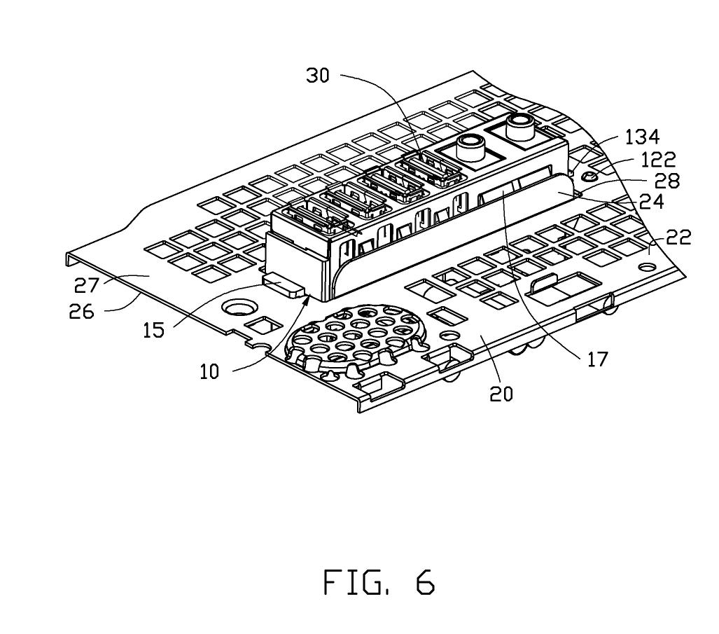

FIGS. 3-6 illustrate in assembly, the mounting tray 10 is located on the bottom surface 26 of the securing plate 20. The mounting tray 10 is inserted into the opening 28, and the clamping piece 15 is engaged with a first edge of the opening 28. At this time, the two positioning posts 122 are aligned with the two positioning holes 29. The mounting tray 10 is moved towards the securing plate 20, until the guiding surface 135 abuts the securing plate 20. The mounting tray 10 is further moved, and the resilient portion 13 is deformable by the securing plate 20. The clipping block 134 extends through the securing plate 20 and engaged with a second edge of the opening 28. The two positioning posts 122 are engaged in the two positioning holes 29. Thus, the mounting tray 10 is secured to the securing plate 10.

In disassembly, the resilient portion 13 is deformable to disengage from the second edge of the opening 28. The two positioning posts 122 are removed from the two positioning holes 29. The clamping piece 15 is disengaged from the first edge of the opening 28, and the mounting tray 10 can be disengaged from the securing plate 20.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus comprising:
a securing plate defining an opening; and the securing plate comprising a bottom surface and a top surface opposite to the bottom surface;
a mounting tray, received in the opening, configured to secure input/output devices; the mounting tray comprising a positioning portion and a resilient portion; and the positioning portion attached to the bottom surface, and the resilient portion comprises a resilient block clipped with a first edge of the opening;
wherein the resilient portion is deformable to disengage the resilient block from the first edge of the opening.

2. The mounting apparatus of claim 1, wherein the positioning portion comprises a main body, the main body defines a through hole, and the resilient portion is moveably received in the through hole.

3. The mounting apparatus of claim 2, wherein the securing plate defines a positioning hole, the positioning portion further comprises a positioning post located on the main body, and the positioning post is engaged in the positioning hole.

4. The mounting apparatus of claim 2, wherein the resilient portion comprises a resilient arm extending through the through hole, and the resilient block extends from the resilient portion.

5. The mounting apparatus of claim 1, wherein the mounting tray comprises a first sidewall, and the positioning portion and the resilient portion extend from the first sidewall.

6. The mounting apparatus of claim 5, wherein the mounting tray further comprises a second sidewall that is substantially parallel to the first sidewall, a clamping piece extends from the second sidewall, and the clamping piece is engaged with a second edge of the opening.

7. The mounting apparatus of claim 6, wherein the clamping piece is substantially L-shaped.

8. The mounting apparatus of claim 1, wherein the securing plate further comprises two resisting panels extending from opposite edges substantially perpendicular to the first edge of the opening, and the mounting tray is located between the two resisting panels.

9. The mounting apparatus of claim 8, wherein two resisting portions are located on opposite sides of the mounting tray, and the resisting portions abut the two resisting panels.

10. A mounting apparatus comprising:
a securing plate defining an opening; and the securing plate comprising a bottom surface and a top surface opposite to the bottom surface;
a mounting tray, received in the opening, configured to secure input/output devices; the mounting tray comprising a clamping piece located on a first side of the mounting tray and a resilient portion located on a second side of the mounting tray; the resilient portion comprises a resilient block clipped with a first edge of the opening; and the clamping piece clipped with a second edge of the opening;
wherein the resilient portion is deformable to disengage the resilient block from the first edge of the opening.

11. The mounting apparatus of claim 10, wherein the mounting tray further comprise a positioning portion, the positioning portion comprises a main body, the main body defines a through hole, and the resilient portion is moveable received in the through hole.

12. The mounting apparatus of claim 11, wherein the securing plate defines a positioning hole, the positioning portion further comprises a positioning post located on the main body, and the positioning post is engaged in the positioning hole.

13. The mounting apparatus of claim 11, wherein the mounting tray comprises a first sidewall, and the positioning portion and the resilient portion extend from the first sidewall.

14. The mounting apparatus of claim 13, wherein the mounting tray further comprises a second sidewall that is substantially parallel to the first sidewall, and the clamping piece extends from the second sidewall.

15. The mounting apparatus of claim 14, wherein the clamping piece is substantially L-shaped.

16. The mounting apparatus of claim 10, wherein the securing plate further comprises two resisting panels extending from opposite edges substantially perpendicular to the first edge of the opening, and the mounting tray is located between the two resisting panels.

17. The mounting apparatus of claim 16, wherein two resisting portions are located on opposite sides of the mounting tray, and the resisting portions abut the two resisting panels.

18. The mounting apparatus of claim 11, wherein the resilient portion comprises a resilient arm extending through the through hole, and the resilient block extends from the resilient portion.

19. The mounting apparatus of claim 10, wherein the resilient block comprises a guiding surface configured to guide the resilient block extending through the securing plate, and the guiding surface is slanted.
